(19) United States
(12) Patent Application Publication
(10) Pub. No.: US 2010/0054054 A1
(43) Pub. Date: Mar. 4, 2010

(54) SEMICONDUCTOR MEMORY DEVICE AND METHOD OF OPERATING THE SAME

(76) Inventors: HYUNG-WOO KIM, Seoul (KR); JONG-SIN YUN, Seoul (KR)

Correspondence Address: F. CHAU & ASSOCIATES, LLC, 130 WOODBURY ROAD, WOODBURY, NY, 11797, US

(21) Appl. No.: 12/538,992

(22) Filed: Aug. 11, 2009

(30) Foreign Application Priority Data
Sep. 4, 2008 (KR) 10-2008-0087443

(51) Int. Cl. G11C 7/00; G11C 5/14; G11C 11/00

(52) U.S. Cl. 365/191; 365/226; 365/156

(57) ABSTRACT

A semiconductor memory device includes a plurality of word lines and a plurality of pairs of bit lines and complementary bit lines that cross the plurality of word lines. A plurality of memory cells is disposed at regions where the word lines and the pairs of bit lines and complementary bit lines cross each other. A voltage control unit includes a plurality of elements connected in parallel, each of which is connected to a power voltage source and is switched on/off based on a control signal that controls an operation of the plurality of memory cells. The voltage control unit controls the voltage of the power voltage source to a predetermined level, thus obtaining a controlled voltage to be applied to the memory cells.

### CROSS-REFERENCE TO RELATED APPLICATIONS

This application claims priority to and the benefit of Korean Patent Application No. 10-2008-0087443, filed on Sep. 4, 2008, in the Korean Intellectual Property Office, the entire content of which is incorporated by reference herein.

### BACKGROUND

The present disclosure relates to memory devices, and more particularly, to a semiconductor memory device that performs a stable write operation and a method of manufacturing the semiconductor memory device.

Semiconductor memory devices, which store data, are largely categorized into volatile memory devices and non-volatile memory devices. Volatile memory devices lose their stored data when their power supplies are removed, while non-volatile memory devices retain their stored data even when their power supplies are removed.

Examples of volatile memory devices include dynamic random access memory (DRAM) devices and static RAM (SRAM) devices. SRAM devices have lower power consumption and operate at a faster speed than DRAM devices, and thus SRAM devices are used as cache memory.

As SRAM memory cells become miniaturized, the size of the cells and the power voltages applied to the cells have decreased. As such, write assist elements that provide power voltages to the typical pair of cross-coupled inverters in the SRAM have become prevalent and the stable application of power voltage from the write assist elements during a write operation becomes needed.

### SUMMARY OF THE INVENTION

In accordance with an exemplary embodiment of the present invention, a semiconductor memory device includes a plurality of word lines; a plurality of pairs of bit lines and complementary bit lines; and a plurality of memory cells, each memory cell being disposed at a region where a respective word line and a pair of a bit line and a complementary bit line cross each other. A voltage control unit includes a plurality of elements connected in parallel, each element being connected to a power voltage source and is switched on/off in response to a control signal that controls an operation of the memory cells. The voltage control unit controls the voltage of the power voltage source to supply a controlled voltage to the memory cells.

The elements may be connected in parallel and include a plurality of switches connected in parallel. The switches may be activated when the control signal directs a write operation to one of the memory cells.

The switches connected in parallel include PMOS transistors connected in parallel that are turned on when the control signal directs the write operation to one of the memory cells. Each of the PMOS transistors may have a source connected to the power voltage source.

When the control signal directs a write operation to one of the memory cells, the voltage control unit may provide the memory cells with the controlled voltage obtained by subtracting an average threshold voltage of the PMOS transistors from the voltage of the power voltage source.

The control signal may include a power gating control signal and a write enable signal.

The voltage control unit may further include: a logic gate that performs a logic operation on the power gating control signal and the write enable signal; and a control switch that is switched on/off in response to an output of the logic gate. The elements connected in parallel may be switched on/off in response to an output of the control switch.

The logic gate may be a NAND gate that performs a NAND operation on the power gating control signal and the write enable signal.

The control switch may be a PMOS transistor that includes a source to which the voltage of the power voltage source is applied and a gate connected to the output terminal of the logic gate.

Each of the plurality of memory cells may include: a first inverter and a second inverter that are cross-coupled to each other and to which the controlled voltage is applied; a first access transistor disposed between a first bit line of the pair and an output terminal of the first inverter and is switched on/off by a first word line of the plurality of word lines; and a second access transistor that is disposed between a first complementary bit line of the pair of corresponding to the first bit line and an output terminal of the second inverter and is switched on/off by the first word line.

The semiconductor memory device may further include at least one dummy cell disposed between the voltage control unit and the plurality of memory cells.

In accordance with an exemplary embodiment, a method of operating a semiconductor memory cell is provided. A plurality of transistor elements are connected in parallel between a power voltage source and the semiconductor memory cell, the memory cell being coupled to a word line and a pair of a bit line and a complementary bit line.

The transistor elements are activated in response to a control signal that controls a write operation of the memory cell. A portion of voltage from the power voltage source is applied to the memory cell as a controlled voltage. The write operation to the memory cell is performed in response to voltages of the word line and the complementary bit lines.

The control signal may include a power gating control signal and a write enable signal.

The transistor elements may include a plurality of transistor switches connected in parallel that are activated when the control signal directs a write operation to the memory cell.

The transistor switches may include PMOS transistors that are switched on when the control signal directs the write operation to the memory cell.

Applying to the memory cell a portion of voltage from the power voltage source may include subtracting an average threshold voltage of the PMOS transistors from the power voltage such that a voltage difference is provided to the memory cell as the controlled voltage.

The memory cell may he an SRAM memory cell and the controlled voltage may be applied as a voltage source for a pair of cross-inverters of the SRAM memory cell.

In accordance with an exemplary embodiment of the present invention, an apparatus for controlling a voltage applied to a power line of cross-coupled inverters in an SRAM device during a write operation is provided. A plurality of transistors are coupled in parallel between a voltage source and the power line. The transistors are configured to be turned during the write operation such that an average threshold voltage of the transistors is subtracted from a voltage of the voltage source and applied to the power line.

The SRAM device may be a CMOS SRAM and the transistors may be PMOS transistors.

The transistors may be each turned on simultaneously in response to a write control signal.

The transistors may be coupled in parallel in a write assist element the write assist element being responsive to a switching element controlling read and write operations of the SRAM device.

### BRIEF DESCRIPTION OF TIE DRAWINGS

Exemplary embodiments of the present invention will be more clearly understood from the following detailed description taken in conjunction with the accompanying drawings in which:

FIG. 1 is a block diagram of a semiconductor memory device according to an exemplary embodiment of the present invention;

FIG. 2 is a circuit diagram of a voltage control unit and a memory cell array included in the semiconductor memory device of FIG. 1;

FIG. 3 is a more detailed circuit diagram of the voltage control unit and the memory cell array of FIG. 2;

FIG. 4 is a flowchart illustrating a method of operating a semiconductor memory device according to an exemplary embodiment of the present invention; and

FIG. 5 is a block diagram of a semiconductor memory device according to an exemplary embodiment of the present invention.

### DETAILED DESCRIPTION OF THE EXEMPLARY EMBODIMENTS

Reference will now be made to the exemplary embodiments which are illustrated in the accompanying drawings. However, the exemplary embodiments are not limited to those embodiments illustrated herein.

It will be understood that when an element, such as a component or region, is referred to as being “on,” “connected to” or “coupled to” another element, it may be directly on, connected or coupled to the other element or intervening elements may be present. Like reference numerals refer to like elements throughout. It will be understood that, although the terms first and second may be used herein to describe various elements, these elements should not be limited by these terms. These terms are only used to distinguish one element from another element. Thus, a first element discussed below could be termed a second element without departing from the teachings of the exemplary embodiments.

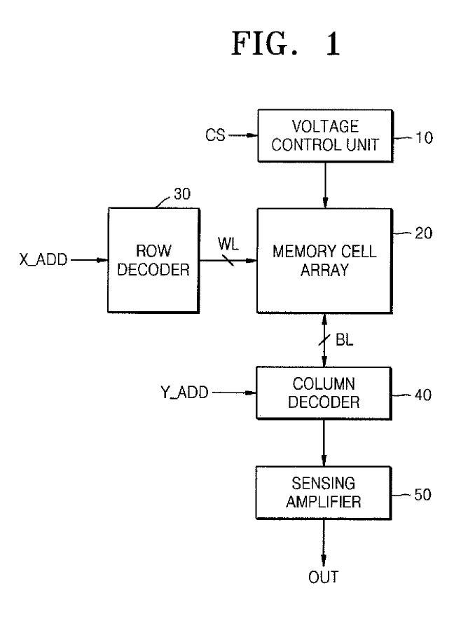

FIG. 1 is a block diagram of a semiconductor memory device according to an exemplary embodiment of the present invention. The semiconductor memory device includes a voltage control unit 10, a memory cell array 20, a row decoder 30, a column decoder 40, and a sensing amplifier 50.

The voltage control unit 10 controls a power voltage applied to the memory cell array 20. More particularly, the voltage control unit 10 controls the magnitude of the power voltage applied to the memory cell array 20 in response to a control signal CS that controls the operation of the memory cell array 20. The memory cell array 20 includes a plurality of memory cells disposed at regions where word lines WLs and bit lines BLs cross each other, and at least one dummy cell.

The row decoder 30 decodes a row address X_ADD to activate a corresponding word line. The column decoder 40 decodes a column address Y_ADD to select a corresponding pair of bit lines. The sensing amplifier 50 amplifies the signals output from the column decoder 40 to generate an output signal.

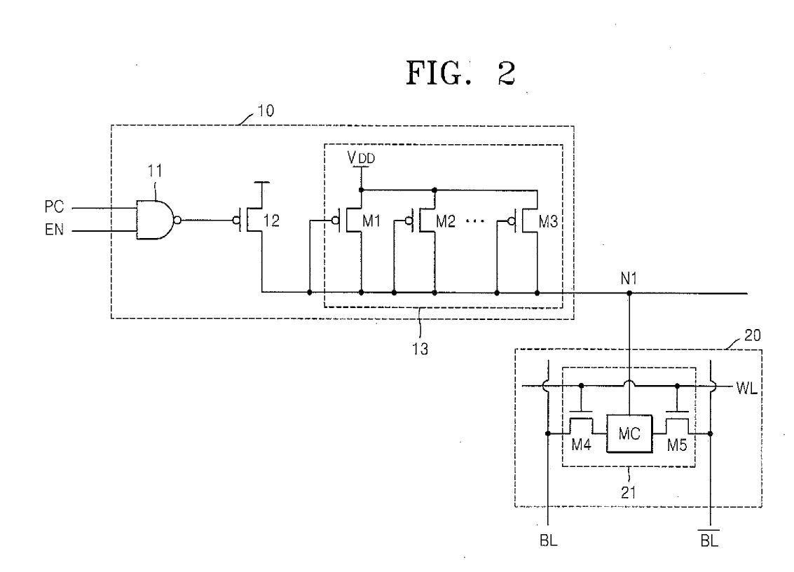

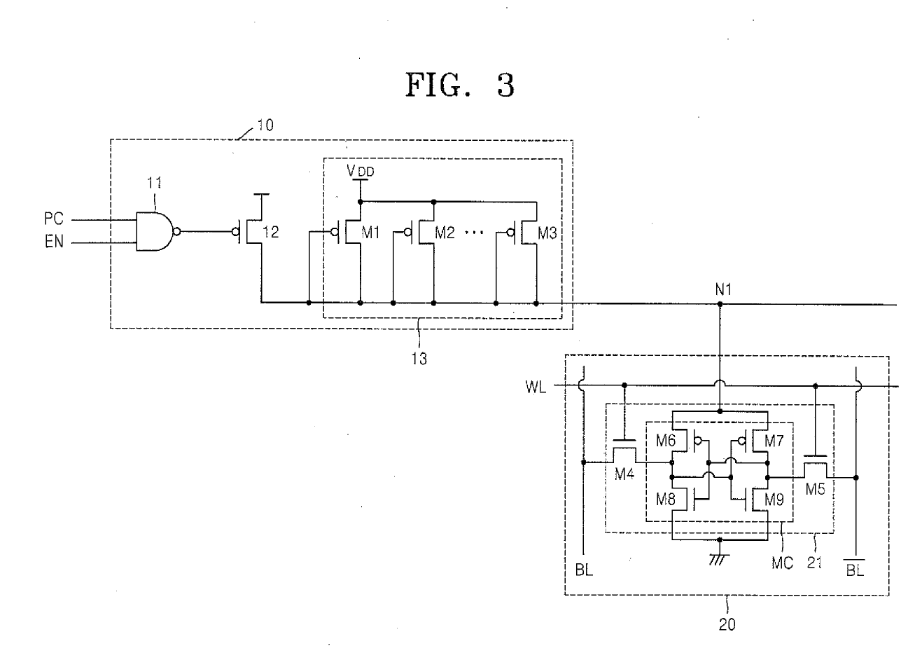

FIG. 2 is a circuit diagram of the voltage control unit 10 and the memory cell array 20 included in the semiconductor memory device of FIG. 1, according to an exemplary embodiment of the present invention. FIG. 3 is a more detailed circuit diagram of the voltage control unit 10 and the memory cell array 20 of FIG. 2.

Referring to FIGS. 2 and 3, the voltage control unit 10 includes a logic gate 11, a switching element 12, and a write assist circuit 13. As noted above, as memory cells have become miniaturized, the size of memory cells and the power voltage applied to the memory cells have decreased. Accordingly, assisting elements that assist the operation of the memory cells have become prevalent. Thus, in an exemplary embodiment the voltage control unit 10 includes a write assist circuit 13.

The memory cell array 20 includes a plurality of memory cells 21. However, only one memory cell 21 is illustrated in FIGS. 2 and 3 as a representative example. In an exemplary embodiment of the present invention, the memory cell 21 is an SRAM cell, but is not limited thereto.

The logic gate 11 performs a logic operation on a power gating control signal PC and a write enable signal EN. In an exemplary embodiment the logic gate 11 is a NAND gate. The power gating control signal PC controls the on/off operation of the voltage control unit 10, and the write enable signal EN is activated when a write operation to the memory cell 21 is performed.

In an exemplary embodiment of the present invention, if the power gating control signal PC is logic “high” and the write enable signal EN is logic “high,” the output of the logic gate 11 is logic “low”, and a read operation from the memory cell 21 is performed. In addition, if the power gating control signal PC is logic “low” and the write enable signal EN is logic “low,” the output of the logic gate 11 is logic “high,” and a write operation to the memory cell 21 is performed. If other logic gates are used as the logic gate 11 instead of a NAND gate, the output of the logic gate 11 in response to the power gating control signal PC and the write enable signal EN may change.

The switching element 12 is switched on/off in response to the output of the logic gate 11, and in an exemplary embodiment the switching element 12 is a PMOS transistor having a source connected to a power voltage source and having a gate to which the output of the logic gate 11 is input. When a read operation from the memory cell 21 is performed, that is, when the output of the logic gate 11 is logic “low,” the switching element 12 is turned on. On the other hand, when a write operation to the memory cell 21 is performed, that is, when the output of the logic gate 11 is logic “high,” the switching element 12 is turned off.

The write assist circuit 13 assists write operations to the memory cell 21. The write assist circuit 13 is not activated when a read operation from the memory cell 21 is performed, and is activated only when a write operation to the memory cell 21 is performed. In an exemplary embodiment of the present invention, the write assist circuit 13 includes a plurality of elements connected in parallel. The elements connected in parallel are PMOS transistors M1, M2, M3, each having the source thereof connected to the power voltage source VDD and having a gate to which a drain voltage of the switching element 12 is input. Although only three PMOS transistors are illustrated in FIG. 3, a greater number of PMOS transistors is also possible.

More particularly, when a read operation from the memory cell 21 is performed, the switching element 12 is turned on, and thus the drain voltage of the switching element 12 is logic “high,” and the plurality of PMOS transistors M1, M2, M3 included in the write assist circuit 13 are turned off. On the other hand, when a write operation to the memory cell 21 is performed, the switching element 12 is turned off, and the plurality of PMOS transistors M1, M2, M3 included in the write assist circuit 13 are turned on. When the plurality of PMOS transistors M1, M2, M3 are turned on, the voltage of a first node N1 between the voltage control unit 10 and the memory cell 21 has a value obtained by subtracting an average threshold voltage ((Vtp1+Vtp2+Vth3)/3) of the PMOS transistors M1, M2, M3 from the voltage VDD of the power voltage source.

As described above, the voltage control unit 10 includes the write assist circuit 13 including PMOS transistors M1, M2, M3 connected in parallel. Thus, when a write operation to the memory cell 21 is performed, the voltage (VDD−(Vtp1+Vtp2+Vth3)/3) obtained by subtracting the average threshold voltage ((Vtp1+Vtp2+Vth3)/3) of the PMOS transistors M1, M2, M3 from the voltage VDD of the power voltage source is applied to the memory cell 21. Accordingly, when a write operation to the memory cell 21 is performed, a voltage drop can stably occur in the write assist circuit 13.

If the write assist circuit 13 includes only one transistor, the amount of voltage drop in the write assist circuit 13 may vary according to variations of the transistor used. Accordingly, the degree of assisting the write operation to the memory cell 21 also varies, and thus a write operation to the memory cell 21 may be unstably performed. However, as described above, the write assist circuit 13 according to the exemplary embodiment includes PMOS transistors M1, M2, M3, and thus, when a write operation to the memory cell 21 is performed, the amount of voltage drop in the write assist circuit 13 is the average threshold voltage of the plurality of PMOS transistors M1, M2, M3. Thus, the variation among the plurality of PMOS transistors M1, M2, M3 is decreased, and thus a voltage drop in the write assist circuit 13 becomes more stable. As a result, the write assist operation to the memory cell 21 can be more stably performed.

In general, a write operation to memory cells is performed by converting a logic “high” stored in the memory cells to logic “low.” When a power voltage applied to each of the memory cells is, as described above, stably decreased to a predetermined voltage or less, the write operation to each of the memory cells may be performed faster and more stably.

The memory cell 21 is connected to the voltage control unit 10 through the first node N1. More particularly, the memory cell 21 is disposed at a region where one WL of the plurality of word lines, and one BL of the plurality of bit lines and the corresponding complementary bit line /BL cross each other. The memory cell 21 includes first and second access transistors M4, M5 that are respectively connected to the word line WL and the bit line BL and the word line WL and the complementary line /BL, and a data storing region MC to which the power voltage from the voltage control unit 10 is applied.

The first access transistor M4 is an NMOS transistor having a gate connected to the word line WL and a drain connected to the bit line BL, and the second access transistor M5 is an NMOS transistor having a gate connected to the word line WL and a source connected to the complementary bit line /BL.

Referring to FIG. 3, the data storing region MC includes a pair of inverters cross-coupled to each other. The data storing region MC includes a first inverter having a first PMOS transistor M6 and a first NMOS transistor M8 and a second inverter having a second PMOS transistor M7 and a second NMOS transistor M9. However, in an exemplary embodiment of the present invention, the data storing region MC may include resistors instead of the first and second PMOS transistors M6, M7.

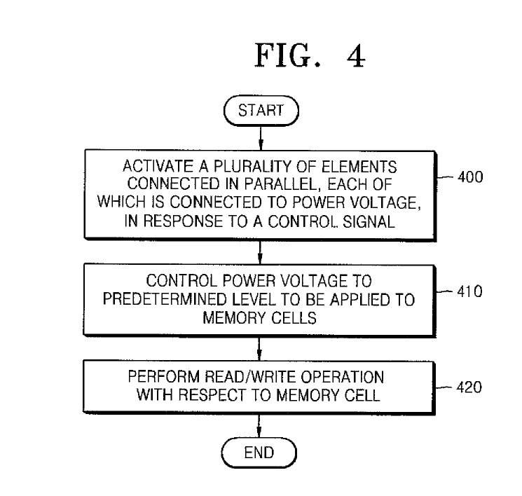

FIG. 4 is a flowchart illustrating a method of operating a semiconductor memory device, according to an exemplary embodiment of the present invention. In step 400, in response to a control signal that controls the operation of a plurality of memory cells, a plurality of elements connected in parallel, each of which is connected to a power voltage source, are activated. The control signal may include a power gating control signal and a write enable signal.

In step 410, when the elements are activated, the power voltage is controlled to a predetermined level, thus obtaining a controlled voltage to be applied to the memory cells. The elements include a plurality of switches connected in parallel which are activated when the control signal directs a write operation to one of the memory cells. In addition, the elements may include PMOS transistors which are switched on when the control signal directs a write operation to one of the memory cells. In this case, in step 410, a controlled voltage obtained by subtracting an average threshold voltage of the PMOS transistors from the power voltage is applied to the memory cells.

In step 420, upon receiving the controlled voltage, a read operation or write operation is performed with respect to the memory cells in response to a voltage of a plurality of word lines and a plurality of bit lines.

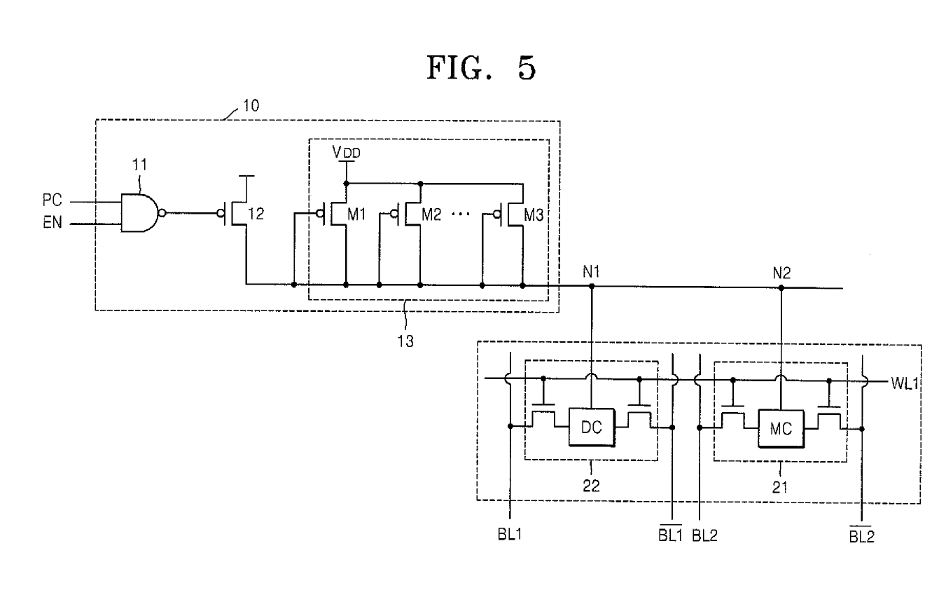

Referring now to FIG. 5, in an exemplary embodiment of the present invention, the semiconductor memory device may further include at least one dummy cell 22 at node N1 between the voltage control unit 10 and the memory cell 21 at node N2. In this case, the dummy cell 22 may have substantially the same structure as that of the memory cell 21. Thus, when a write operation to the memory cell 21 is performed, a stable reduced voltage in the write assist circuit 13 may be applied to the dummy cell 22 allowing the write operation to be performed in the memory cell 21 at an even faster speed given the current draw of dummy cell 22 and the resultant voltage drop at node N2 from the voltage at node N1.

While the present invention has been described with regard to exemplary embodiments of SRAM devices, exemplary embodiments of the present invention may also include a method and apparatus for applying compute readable codes onto various other compute readable recording medium. The compute readable recording medium is any data storage device that can store data which can be thereafter read by a computer system. Examples of the computer readable recording medium include read-only memory (ROM), random-access memory (RAM), CD-ROMs, magnetic tapes, floppy disks and optical data storage devices. The computer readable code can also be distributed over network coupled computer systems so that the computer readable code can be stored and executed in a distributed fashion. Here, a program stored in a recording medium is expressed in a series of instructions used directly or indirectly within a device with a data processing capability, such as, computers. Thus, a term “computer” involves all devices with data processing capability in which a particular function is performed according to a program using a memory, input/output devices, and arithmetic logic.

Although exemplary embodiments of the present invention have been described, those skilled in the art will readily appreciate that many modifications are possible to the exemplary embodiments. Accordingly, all such modifications are intended to be included within the scope of the following claims.

1. A semiconductor memory device comprising:
a plurality of word lines;
a plurality of pairs of bit lines and complementary bit lines;
a plurality of memory cells, each memory cell being disposed at a region where a respective word line and a pair of a bit line and a complementary bit line cross each other; and
a voltage control unit comprising a plurality of elements connected in parallel, each element being connected to a power voltage source and switched on/off in response to a control signal that controls an operation of the memory cells,
wherein the voltage control unit controls the voltage of the power voltage source to supply a controlled voltage to the memory cells.

2. The semiconductor memory device of claim 1,
wherein the elements connected in parallel comprise a plurality of switches connected in parallel, and
wherein the switches are activated when the control signal directs a write operation to one of the memory cells.

3. The semiconductor memory device of claim 2,
wherein the switches connected in parallel comprise PMOS transistors connected in parallel that are turned on when the control signal directs the write operation to one of the memory cells, and
wherein each of the PMOS transistors has a source connected to the power voltage source.

4. The semiconductor memory device of claim 3, wherein when the control signal directs a write operation to one of the memory cells, the voltage control unit provides the memory cells with the controlled voltage obtained by subtracting an average threshold voltage of the PMOS transistors from the voltage of the power voltage source.

5. The semiconductor memory device of claim 1, wherein the control signal comprises a power gating control signal and a write enable signal.

6. The semiconductor memory device of claim S, wherein the voltage control unit former comprises:
a logic gate that performs a logic operation on the power gating control signal and the write enable signal; and
a control switch that is switched on/off in response to an output of the logic gate,
wherein the elements connected in parallel are switched on/off in response to an output of the control switch.

7. The semiconductor memory device of claim 6, wherein the logic gate is a NAND gate that performs a NAND operation on the power gating control signal and the write enable signal.

8. The semiconductor memory device of claim 6, wherein the control switch is a PMOS transistor that comprises a source to which the voltage of the power voltage source is applied and a gate connected to the output terminal of the logic gate.

9. The semiconductor memory device of claim 1, wherein a memory cell comprises:
a first inverter and a second inverter that are cross-coupled to each other and to which the controlled voltage is applied;
a first access transistor that is disposed between a first bit line of the pair and an output terminal of the first inverter and is switched on/off by a first word line of the plurality of word lines; and
a second access transistor that is disposed between a first complementary bit line of the pair corresponding to the first bit line and an output terminal of the second inverter and is switched on/off by the first word line.

10. The semiconductor memory device of claim 9, further comprising at least one dummy cell disposed between the voltage control unit and the plurality of memory cells.

11-14. (canceled)

15. An apparatus for controlling a voltage applied to a power line of cross-coupled inverters in an SRAM device during a write operation, the apparatus comprising a plurality of transistors coupled in parallel between a voltage source and the power line, the transistors being configured to turn on during the write operation such that an average threshold voltage of the transistors is subtracted from a voltage of the voltage source and is applied to the power line.

16. The apparatus of claim 15, wherein the SRAM device is a CMOS SRAM and the transistors are PMOS transistors.

17. The apparatus of claim 15, wherein the transistors are each turned on simultaneously in response to a write control signal.

18. The apparatus of claim 15, wherein the transistors are coupled in parallel in a write assist element, the write assist element being responsive to a switching element controlling read and write operations of the SRAM device.
